(19) United States
(12) Patent Application Publication
(10) Pub. No.: US 2016/0315620 A1
(43) Pub. Date: Oct. 27, 2016

(54) AN EXTENSIBLE AND CONFIGURABLE LOGIC ELEMENT, AND AN FPGA DEVICE

(71) Applicant: CAPITAL MICROELECTRONICS CO., LTD., Beijing (CN)

(72) Inventors: Ping FAN, Beijing (CN); Jia GENG, Beijing (CN); Yuanpeng WANG, Beijing (CN)

(73) Assignee: CAPITAL MICROELECTRONICS CO., LTD., Beijing (CN)

(21) Appl. No.: 14/761,429

(22) PCT Filed: Dec. 11, 2014
(86) PCT No.: PCT/CN2014/093570

§ 371 Date: Jul. 16, 2015

(51) Int. Cl. H03K 19/177; G06F 7/501; H03K 19/173

(52) U.S. Cl. CPC H03K 19/17728; H03K 19/1737; G06F 7/501

(57) ABSTRACT

An extensible and configurable logic element, wherein the logic element includes: multiple logic parcels, each logic parcel includes two logic cells; each logic cell includes seven inputs, three outputs, an addition carry input, an addition carry output, a six-input and two-output look-up table, a one bit full adder, a first register, and a second register; wherein, the first register stores a signal output by the first output of the look-up table or a carry signal of the full adder according to the configuration; the second register stores a signal output by the second output of the look-up table or an output signal of the full adder according to the configuration; the addition carry output in the current logic cell is connected to the addition carry input in the higher logic cell of the current logic cell, including an addition carry chain in the logic element.

### TECHNICAL FIELD

The present invention relates to the field of integrated circuit technologies, and in particular, to an extensible and configurable logic element, and an FPGA device.

### Related Art

A field-programmable gate array (Field-Programmable Gate Array, FPGA) is a logic device having rich hardware resources, powerful parallel processing capabilities, and flexible reconfigurability. The FPGA has been widely applied in many fields such as data processing, communications, and networks due to these features.

The FPGA is composed of three kinds of logic cells: configurable logic blocks (CLB), configurable input-output cells, and internal internet resource.

Wherein, multiple configurable CLBs are arranged in an array structure in a regular pattern, and distributed throughout the FPGA. Each CLB comprises logic elements (Logic Element, LE), and Xbars, LE usually can implement a variety of logic functions. The configurability and flexibility of LE may directly affect the performance of FPGA.

### SUMMARY

The present invention provides an extensible and configurable logic element and an FPGA device. The logic element supports multiple configuration modes, and can implement a variety of logic functions, including output constant, a look-up table, registers, full adder, and their direct combinational logic functions, having excellent configuration flexibility and extensibility.

According to a first aspect, an embodiment of the present invention provides an extensible and configurable logic element, comprising:

a plurality of logic parcels, each logic parcel includes two logic cells;

each logic cell includes seven inputs, three outputs, an addition carry input, an addition carry output, a six-input and two-output look-up table, a one bit full adder, a first register, and a second register;

wherein, the first register stores a signal output by the first output of the look-up table or a carry signal of the full adder according to the configuration;

the second register stores a signal output by the second output of the look-up table or an output signal of the full adder according to the configuration;

the addition carry output in the current logic cell is connected to the addition carry input in the higher logic cell of the current logic cell, forming an addition carry chain in the logic element.

Preferably, the logic element also includes at least four groups of 2-to-1 multiplexers;

two inputs of a first group of 2-to-1s multiplexers are respectively connected to the second output of a look-up table of the first logic cell in the 2mth logic parcel and the second output of a look-up table of the first logic cell in the (2m+1)th logic parcel;

two inputs of a second group of 2-to-1 multiplexers are respectively connected to the second output of a look-up table of the second logic cell in the 2m logic parcel and the second output of a look-up table of the second logic cell in the (2m+1)th logic parcel;

two inputs of a third group of 2-to-1 multiplexers are respectively connected to the output of the 2nth 2-to-1 multiplexer and the output of the (2n+1)th 2-to-1 multiplexer in the first group of 2-to-1 multiplexers;

two inputs of a fourth group of 2-to-1 multiplexers are respectively connected the output of the 2nth 2-to-1 multiplexer and the output of the (2n+1) 2-to-1 multiplexer in the second group of 2-to-1 multiplexers;

wherein, m and n are the natural number.

Further, preferably, when the six-input and two-output look-up table is used to implement a 4-to-1 logic function,
through the first group of 2-to-1 multiplexers, and the second group of 2-to-1 multiplexers, to implement an 8-to-1 logic function respectively;

through the third group of 2-to-1 multiplexers, and the fourth group of 2-to-1 multiplexers, to implement a 16-to-1 logic function respectively.

Further, preferably, the three outputs are respectively:

a first output, connected to the output of the second register, for outputting a signal output by the second register;

a second output, connected to the second output of the six-input and two-output look-up table, for outputting a signal output by the second output of the six-input and two-output look-up table;

a third output, connected to a configuration multiplexer, to output one of a signal output by the first register, a carry signal of the full adder, an output signal of the full adder, a signal output by the first output of the look-up table, an 8-to-1 logic output signal, a 16-to-1 logic output signal or a signal output by the second register in a multiplexed manner according to the configuration of the configuration multiplexer.

Further, preferably, the plurality of logic parcels are specifically four logic parcels, the first group of 2-to-1 multiplexers are specifically two 2-to-1 multiplexers, the second group of 2-to-1 multiplexers are specifically two 2-to-1 multiplexers, the third group of 2-to-1 multiplexers are specifically one 2-to-1 multiplexer, the fourth group of 2-to-1 multiplexers are specifically one 2-to-1 multiplexer.

Further, preferably, the seven inputs are respectively:

six data inputs, for inputting data signals to the six-to-one multiplexer;

a bypass signal input, for providing a gate signal to the third group of 2-to-1 multiplexers or the fourth group of 2-to-1 multiplexers.

Further, preferably, the sixth data input in the six data inputs is also used to input an addend to the one bit full adder.

Preferably, in a logic cell, the addition carry input is connected to the input of the one bit full adder, the addition carry output is connected to the output of the one bit full adder.

According to a second aspect, an embodiment of the present invention provides an FPGA device, where the FPGA device comprises a plurality of the logic elements according to the foregoing first aspect, and a plurality of Xbars;

each Xbar is connected to a logic element, for providing a clock signal to a register in the logic element.

Preferably, the logic element is also used to provide a lowest carry signal to the carry chain in the logic element.

The extensible and configurable logic element provided by this embodiment of the present invention supports multiple configuration modes, and can implement a variety of logic functions, including output constant, a look-up table, registers, a full adder, and their direct combinational logic functions, leading to excellent configuration flexibility and extensibility. Using this logic element, the layout structure and area of an FPGA chip can be optimized.

### BRIEF DESCRIPTION OF THE DRAWINGS

FIG. 1 is a schematic diagram of a structure of a configurable logic block (CLB) according to an embodiment of the present invention;

FIG. 2 is a schematic diagram of a logic parcel of a logic element according to an embodiment of the present invention.

The technical solutions of the present invention are further described in detail in the following with reference to accompanying drawings and embodiments.

### DETAILED DESCRIPTION

To make the objectives, technical solutions and advantages of the present invention more clear, the present invention is described in detail in the following with reference to accompanying drawings. Obviously, the described embodiments are merely some but not all of the embodiments of the present invention. All other embodiments obtained by a person of ordinary skill in the art based on the embodiments of the present invention without creative efforts shall fall within the protection scope of the present invention.

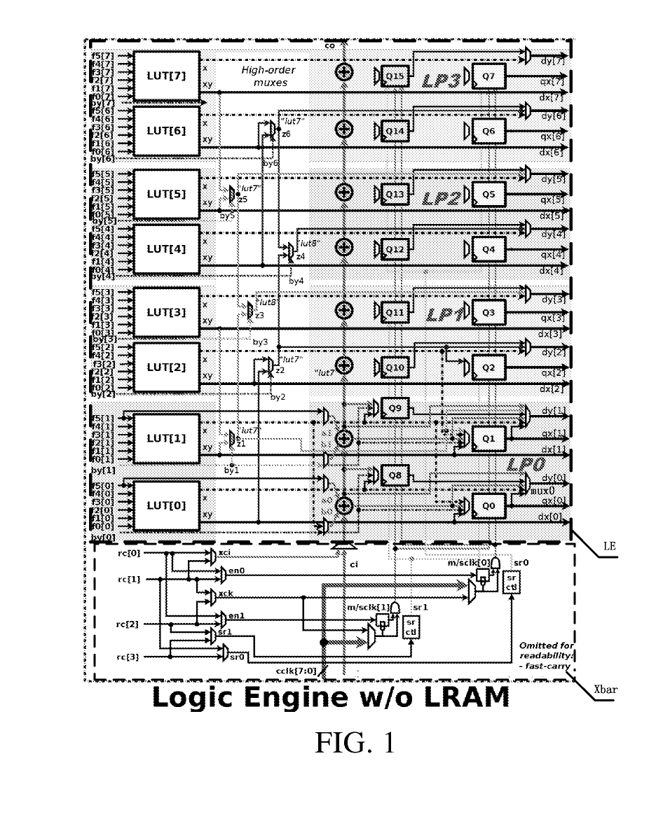

FIG. 1 is a schematic diagram of a structure of a configurable logic block (CLB) according to an embodiment of the present invention. As shown in FIG. 1, CLB includes a logic element (Logic Element, LE) and an Xbar. Wherein, the Xbar is connected to the LE, for providing a clock signal to LE, and providing a lowest carry signal to the carry chain in LE.

Take FIG. 1, for instance, the LE of an embodiment of the present invention includes: four logic parcels (Logic Parcel, LP) (LP0-LP3), each LP includes two logic cells (Logic cell, LC).

Each LC includes: seven inputs (by, f0-f5), three outputs(dx, qx, dy), an addition carry input, an addition carry output, a six-input and two-output look-up table (LUT), a one bit full adder, a first register, and a second register.

Wherein, LP0 in FIG. 1 shows the connection relations of each port with the look-up table, the full adder and the registers etc in LP. Take LP0 as an example to illustrate below.

In the bottom LC in LP0, the first register Q8 stores a signal x output by the first output of the look-up table LUT[0], or a carry signal of the full adder, or a bypass input signal by [0]according to the configuration;

the second register Q0 stores a signal xy output by the second output of the look-up table LUT[0],or an output signal of the full adder, or a bypass input signal by [0], or a signal x output by the first output of LUT[1]according to the configuration.

In this LC, the addition carry input accesses a lowest carry signal provided by Xbar, the addition carry output is connected to the addition carry input in the higher LC.

In addition, the LE also includes four groups of 2-to-1 multiplexers;

a first group of 2-to-1 multiplexers include z2 and z6, a second group of 2-to-1 multiplexers include z1 and z5;

a third group of 2-to-1 multiplexer is z4, two inputs of which are respectively connected to the output of the z2 and the output of the z6 in the first group of 2-to-1 multiplexers;

a fourth group of 2-to-1 multiplexer is z3, two inputs of which are respectively connected to the output of the z1 and the output of the z5 in the second group of 2-to-1 multiplexers;

through the first group of 2-to-1 multiplexers, and the second group of 2-to-1 multiplexers, can implement a 8-to-1 logic function respectively;

through the third group of 2-to-1 multiplexers, the fourth group of 2-to-1 multiplexers, can implement a 16-to-1 logic function respectively.

The above only takes LE shown in FIG. 1 as an example to illustrate, in other examples, when a LE includes more LUTs, also can have a fifth group, a sixth group . . . of 2-to-1 multiplexers to implement a thirty-two selected, a sixty-4-to-1 . . . logic function.

Specifically, referring to FIG. 1 again, when the six-input and two-output look-up table LUT[0]and LUT[2]in LE are used to implement a 4-to-1 logic function, it can implement a 8-to-1 logic function through z2;

when z2 and z6 are respectively to implement a 8-to-1 logic function, it also can implement a 16-to-1 logic function through z4, and output results through by dy[4].

In the seven inputs, the data inputs (f0-f5) are used to input data signals to the six-to-one multiplexer; the bypass signal input is used to provide a gate signal to the third group of 2-to-1 multiplexers or the fourth group of 2-to-1 multiplexers.

In a LC, the addition carry input of LC is connected to the input of the one bit full adder in LC, the addition carry output of LC is connected to the output of the one bit full adder.

The first output (qx), connected to the output of the second register, for outputting a signal output by the second register Q0;

the second output (dx), connected to the second output xy of the six-input and two-output look-up table LUT[0], for outputting a signal output by the second output of the six-input and two-output look-up table LUT[0];

the third output (dy), connected to a configuration multiplexer mux0, to output one of a signal output by the first register Q8, a carry signal of the full adder, an output signal of the full adder, a signal output by the first output x of the look-up table LUT[0], or a signal output by the second register Q0 in a multiplexed manner according to the configuration of the configuration multiplexer mux0.

In other LC, the configuration multiplexer connected to the third output dy is also used to configure and output a 8-to-1 logic output signal (such as in the top of the LC in LP0) or a 16-to-1 logic gate signal(such as in the top LC in LP1) in a multiplexed manner.

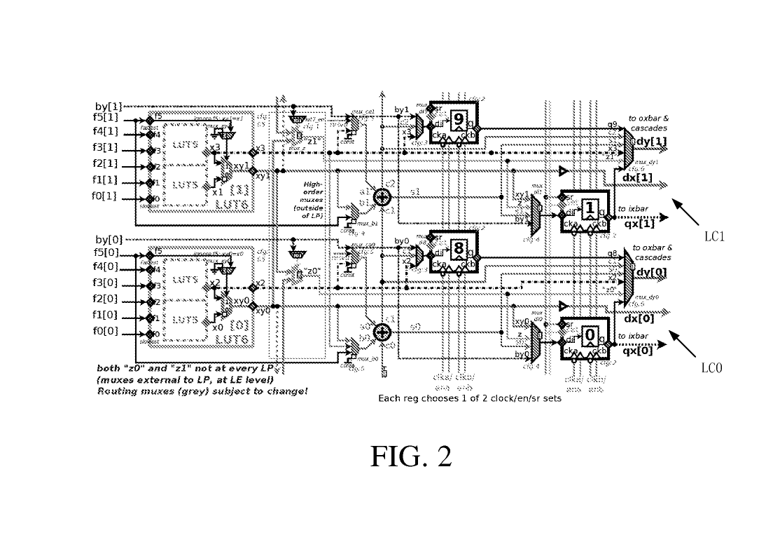

In order to illustrate the structure of LE of the present invention more clearly, FIG. 2 of an embodiment of the present invention provides a schematic diagram of a LP of a LE, where each LP includes two LCs.

In an example shown in FIG. 2, you can see in LC0, an input of the one bit full adder inputs a signal in a multiplexed manner by two multiplexers. Wherein, the input signal a0 can be provided by 0, or provided by the first output x2 of LUT6, or constant. The input signal b0 can be provided by the f5[0], or provided by the second output xy0 of LUT6, or provided by the first output x3 of LC1, or constant.

When the input and output of this LC are occupied by the other logic, and may not be used to implement the addition logic, on this carry chain, the LP, can still configure constants to 0 and 1, and configure a multiplexer to make its output as an addend, the adder in this LC is implemented to send the carry input signal C0 to the carry output C1. So when the input and output of LC are occupied by the other logic, it can keep maintaining the continuity of carry chain through this kind of structure to avoid being forced to interrupt.

In addition to the above way, two constants can be configured to 0 and 0 respectively, for producing a constant full adder carry output signal to 0. Or two constants can be configured to 1 and 1 respectively, for producing a constant full adder carry output signal to 1. Thus can be used as the lowest carry input of the addition carry chain, to make the starting position of the carry chain is no longer restricted by the FPGA architecture, but can start from any one of positions on the carry chain.

Moreover, the output of the multiplexer used to input the addend a0 has an optional invert logic configuration, for the operation needing a great deal of reversing and adding, can greatly reduce the usage of the logic resource, thus implements the optimization of the layout structure and parcel of an chip.

In the example shown in FIG. 2, the six-input LUT may be configured to either of the following two modes: a six-input LUT mode or a mode with two five-input LUTs. Of course, the six input look-up table can also be configured to output constant.

That is to say, a six input look-up table of a LC, can implement the output of constants, as well as any one of the logic outputs of LUT1, LUT2, LUT3, LUT4, LUT5 and LUT6, or arbitrary two of the logic outputs of LUT1, LUT2 , LUT3, LUT4 and LUT5.

The extensible and configurable logic element provided by this embodiment of the present invention, can implement a variety of logic functions, for instance, can implement any one of the logic functions of the output constant, LUT1 and LUT2, LUT3, LUT4, LUT5, LUT6, registers, a full adder through a LC; can also implement arbitrary two of the logic functions of LUT1, LUT2, LUT3, LUT4 and LUT5, a logic function of LUT and registers, as well as a logic function of a full adder and registers.

In LE, it can also implement a higher order combination logic function of an 8-to-1, a16-to-1, and eight bits full adder etc through a combination of LCs.

The LE of the present invention supports multiple configuration modes, having excellent configuration flexibility and extensibility. When being applied with the LE, the FPGA will have more flexible FPGA logic application, and optimized layout structure and area.

Persons skilled in the art may further realize that, in combination with the embodiments herein, cells and algorithm, steps of each example described can be implemented with electronic hardware, computer software, or the combination thereof. In order to clearly describe the interchangeability between the hardware and the software, compositions and steps of each example have been generally described according to functions in the foregoing descriptions. Whether the functions are executed in a mode of hardware or software depends on particular applications and design constraint conditions of the technical solutions. Persons skilled in the art can use different methods to implement the described functions for each particular application, but it should not be considered that the implementation goes beyond the scope of the embodiments of the present invention.

In combination with the embodiments herein, steps of the method or algorithm described may be directly implemented using hardware, a software module executed by a processor, or the combination thereof. The software module may be placed in a random access memory (RAM), a memory, a read-only memory (ROM), an electrically programmable ROM (EPROM), an electrically erasable programmable ROM (EEPROM), a register, a hard disk, a removable magnetic disk, a CD-ROM, or any storage medium of other forms well-known in the technical field.

The objectives, technical solutions, and beneficial effects of the present invention have been described in further detail through the above specific embodiments. It should be understood that the above descriptions are merely specific embodiments of the present invention, but not intended to limit the present invention. Any modification, equivalent replacement, or improvement made without departing from the spirit and principle of the present invention should fall within the scope of the present invention.

1. An extensible and configurable logic element, wherein the logic element comprises:
a plurality of logic parcels, each logic parcel includes two logic cells;
each logic cell includes seven inputs, three outputs, an addition carry input, an addition carry output, a six-input and two-output look-up table, a one bit full adder, a first register, and a second register;
wherein, the first register stores a signal output by the first output of the look-up table or a carry signal of the full adder according to the configuration;
the second register stores a signal output by the second output of the look-up table or an output signal of the full adder according to the configuration;
the addition carry output in the current logic cell is connected to the addition carry input in the higher logic cell of the current logic cell, forming an addition carry chain in the logic element.

2. The logic element according to claim 1, wherein the logic element also includes at least four groups of 2-to-1 multiplexers;
two inputs of a first group of 2 to 1 multiplexers are respectively connected to the second output of a look-up table of the first logic cell in the 2mth logic parcel and the second output of a look-up table of the first logic cell in the (2m+1)th logic parcel;
two inputs of a second group of 2-to-1 multiplexers are respectively connected to the second output of a look-up table of the second logic cell in the 2mth logic parcel and the second output of a look-up table of the second logic cell in the (2m+1)th logic parcel;
two inputs of a third group of 2-to-1 multiplexers are respectively connected to the output of the 2nth 2-to-1 multiplexer and the output of the (2n+1)th 2-to-1 multiplexer in the first group of 2-to-1 multiplexers;
two inputs of a fourth group of 2-to-1 multiplexers are respectively connected to the output of the 2nth 2-to-1 multiplexer and the output of the (2n+1)th 2-to-1 multiplexer in the second group of 2-to-1 multiplexers;
wherein, m and n are the natural number.

3. The logic element according to claim 2, wherein when the six-input and two-output look-up table is used to implement a 4-to-1 logic function,
through the first group of 2-to-1 multiplexers, and the second group of 2-to-1 multiplexers, to implement an 8-to-1 logic function respectively;
through the third group of 2-to-1 multiplexers, and the fourth group of 2-to-1 multiplexers, to implement a 16-to-1 logic function respectively.

4. The logic element according to claim 3, wherein the three outputs are respectively:
a first output, connected to the output of the second register, for outputting a signal output by the second register;
a second output, connected to the second output of the six-input and two-output look-up table, for outputting a signal output by the second output of the six-input and two-output look-up table;
a third output, connected to a configuration multiplexer, to output one of a signal output by the first register, a carry signal of the full adder, an output signal of the full adder, a signal output by the first output of the look-up table, an 8-to-1 logic output signal, a 16-to-1 logic output signal or a signal output by the second register in a multiplexed manner according to the configuration of the configuration multiplexer.

5. The logic element according to claim 2, wherein the plurality of logic parcels are specifically four logic parcels, the first group of 2-to-1 multiplexers are specifically two 2-to-1 multiplexers, the second group of 2-to-1 multiplexers are specifically two 2-to-1 multiplexers, the third group of 2-to-1 multiplexers are specifically one 2-to-1 multiplexer, the fourth group of 2-to-1 multiplexers are specifically one 2-to-1 multiplexer.

6. The logic element according to claim 2, wherein the seven inputs are respectively:
six data inputs, for inputting data signals to the six-to-one multiplexer;
a bypass signal input, for providing a gate signal to the third group of 2-to-1 multiplexers or the fourth group of 2-to-1 multiplexers.

7. The logic element according to claim 6, wherein the sixth data input in the six data inputs is also used to input an addend to the one bit full adder.

8. The logic element according to claim 1, wherein in a logic cell, the addition carry input is connected to the input of the one bit full adder, the addition carry output is connected to the output of the one bit full adder.

9. An FPGA device, wherein the FPGA device comprises a plurality of the logic elements according to claim 1, and a plurality of Xbars;
each Xbar is connected to a logic element, for providing a clock signal to a register in the logic element.

10. The FPGA device according to claim 9, wherein the logic element is also used to provide a lowest carry signal to the carry chain in the logic element.

11. An FPGA device, wherein the FPGA device comprises a plurality of the logic elements according to claim 2, and a plurality of Xbars;
each Xbar is connected to a logic element, for providing a clock signal to a register in the logic element.

12. An FPGA device, wherein the FPGA device comprises a plurality of the logic elements according to claim 3, and a plurality of Xbars;
each Xbar is connected to a logic element, for providing a clock signal to a register in the logic element.

13. An FPGA device, wherein the FPGA device comprises a plurality of the logic elements according to claim 4, and a plurality of Xbars;
each Xbar is connected to a logic element, for providing a clock signal to a register in the logic element.

14. An FPGA device, wherein the FPGA device comprises a plurality of the logic elements according to claim 5, and a plurality of Xbars;
each Xbar is connected to a logic element, for providing a clock signal to a register in the logic element.

15. An FPGA device, wherein the FPGA device comprises a plurality of the logic elements according to claim 6, and a plurality of Xbars;
each Xbar is connected to a logic element, for providing a clock signal to a register in the logic element.

16. An FPGA device, wherein the FPGA device comprises a plurality of the logic elements according to claim 7, and a plurality of Xbars;
each Xbar is connected to a logic element, for providing a clock signal to a register in the logic element.

17. An FPGA device, wherein the FPGA device comprises a plurality of the logic elements according to claim 8, and a plurality of Xbars;
each Xbar is connected to a logic element, for providing a clock signal to a register in the logic element.

18. The FPGA device according to claim 11, wherein the logic element is also used to provide a lowest carry signal to the carry chain in the logic element.

19. The FPGA device according to claim 12, wherein the logic element is also used to provide a lowest carry signal to the carry chain in the logic element.

20. The FPGA device according to claim 13, wherein the logic element is also used to provide a lowest carry signal to the carry chain in the logic element.
